(19) United States
(12) Patent Application Publication
(10) Pub. No.: US 2025/0125132 A1
(43) Pub. Date: Apr. 17, 2025

(54) Substrate Processing Apparatus

(71) Applicant: Tokyo Electron Limited, Tokyo (JP)

(72) Inventors: Naoki KUBOTA, Tokyo (JP); Hiroshi SONE, Tokyo (JP)

(21) Appl. No.: 18/911,171

(22) Filed: Oct. 9, 2024

(30) Foreign Application Priority Data
Oct. 16, 2023 (JP) 2023-177985

(51) Int. Cl. H01J 37/34; C23C 14/35; C23C 14/54; H01J 37/32

(52) U.S. Cl. CPC H01J 37/3441; C23C 14/35; C23C 14/54; H01J 37/32513; H01J 37/32522; H01J 2237/20214; H01J 2237/332

(57) ABSTRACT

A substrate processing apparatus comprises a processing chamber having a ceiling and a cathode part installed at the ceiling and configured to sputter a target. The ceiling has an engagement portion around the target. The cathode part includes a first shield member having an attachment portion to be attached to the engagement portion and a conductive seal member configured to electrically connect the ceiling and the first shield member.

### CROSS-REFERENCE TO RELATED APPLICATIONS

This application claims priority to Japanese Patent Application No. 2023-177985 filed on Oct. 16, 2023, the entire contents of which are incorporated herein by reference.

### TECHNICAL FIELD

The present disclosure relates to a substrate processing apparatus.

### Background

Japanese Laid-open Patent Publication No. H5-195218 proposes a sputtering apparatus in which at least a target side surface of a substrate holder is covered with a material having a linear expansion coefficient close to that of a target material, and at least a target adhesion preventive plate is provided with a device for controlling a temperature to a level close to a temperature of a sputtered film adhesion portion during sputtering.

Japanese Laid-open Patent Publication No. 2010-84169 provides a vacuum evacuation method for a vacuum processing apparatus in which an adhesion preventive shield is disposed in a vacuum chamber and plasma is produced in an evacuated state to form a thin film on a substrate. The vacuum evacuation method includes a step of introducing an inert gas, a step of heating the adhesion preventive shield with a lamp heater under a pressure of the inert gas, and a step of evacuating the vacuum chamber with an evacuation device.

International Publication No. WO 2012/046705 proposes a film forming apparatus including an adhesion preventive plate disposed at a position where particles released from a target are adhered, and an adhesion preventive plate heating part for heating the adhesion preventive plate. In the film forming apparatus, a sputtering gas is introduced into a vacuum chamber from a sputtering gas inlet part, and the adhesion preventive plate is heated to a temperature higher than a film forming temperature. Vapor is released from a thin film adhered to the adhesion preventive plate, and a seed layer is formed on a substrate. The substrate is heated to the film forming temperature, and an AC voltage is applied from a power supply to the target. The target is sputtered, and a dielectric film is formed on the substrate.

### SUMMARY

The present disclosure provides a substrate processing apparatus capable of avoiding occurrence of abnormal discharge.

According to one embodiment of the present disclosure, a substrate processing apparatus is provided. The substrate processing apparatus includes a processing chamber having a ceiling and a cathode part installed at the ceiling and configured to sputter a target, wherein the ceiling has an engagement portion around the target, the cathode part includes a first shield member having an attachment portion to be attached to the engagement portion and a conductive seal member configured to electrically connect the ceiling and the first shield member.

### BRIEF DESCRIPTION OF THE DRAWINGS

FIG. 1 is a schematic cross-sectional view showing an example of a substrate processing apparatus according to an embodiment.

FIG. 2 is an enlarged view of a cathode part.

FIGS. 3A and 3B show an example of a configuration of a first shield member.

FIG. 4 shows an example of a configuration of a second shield member and a shield cap.

FIG. 5 shows an example of a dedicated tool for installing the shield cap.

### DETAILED DESCRIPTION

Hereinafter, embodiments of the present disclosure will be described in detail with reference to the accompanying drawings. Like reference numerals will be given to like or corresponding parts throughout the drawings, and redundant description thereof may be omitted.

### Substrate Processing Apparatus

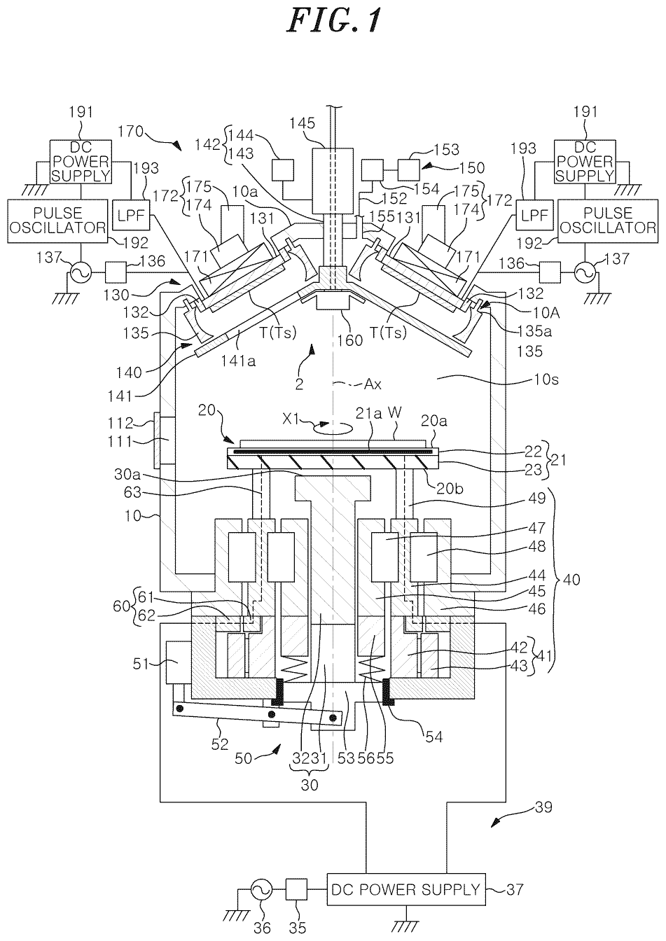

A substrate processing apparatus 1 will be described with reference to FIG. 1. FIG. 1 is a schematic cross-sectional view showing an example of the substrate processing apparatus 1 according to an embodiment. The substrate processing apparatus 1 is a vacuum processing apparatus, and is a physical vapor deposition (PVD) sputtering apparatus (film forming apparatus). The substrate processing apparatus 1 is a magnetron sputtering apparatus having a cathode part 2 as a sputtering source at a ceiling (lid) 10a of a processing chamber 10.

The substrate processing apparatus 1 includes a processing chamber 10 and a placing table 20. The placing table 20 places a substrate W thereon. The cathode part 2 is disposed above the placing table 20, and is configured to sputter a target T installed at the ceiling 10a. The sputtered particles (film forming atoms) released from the target T are attached (deposited) on the surface of a substrate W such as a semiconductor wafer placed on the placing table 20, thereby performing film formation on the substrate W. A processing space 10s is defined by the sidewall, the ceiling 10a, and the placing table 20 of the processing chamber 10.

The cathode part 2 disposed at the ceiling 10a has a substantially pyramid shape (e.g., a substantially quadrilateral pyramid shape, a conical shape, or the like). A central axis Ax is located at the center of the processing chamber 10, and is set to pass through the upper end of the ceiling 10a, extend along the vertical direction, and pass through the center of the placing table 20. The center of a placing surface 20a of the placing table 20 coincides with the central axis Ax.

The processing chamber 10 is made of, e.g., aluminum. The processing chamber 10 is connected to a ground potential. In other words, the processing chamber 10 is grounded. The processing chamber 10 has a loading/unloading port 111 that connects a processing space 10s and the outside of the processing chamber 10, and a gate valve 112 that opens and closes the loading/unloading port 111. In the substrate processing apparatus 1, when the gate valve 112 is opened, the substrate W is loaded and unloaded through the loading/unloading port 111 by a transfer device (not shown). An exhaust device (not shown) such as a vacuum pump or the like evacuates the processing chamber 10 so that the processing space 10s is maintained in a desired vacuum (depressurized) state.

The placing table 20 has an electrostatic chuck 21, a freezing device 30, and a power supply controller 39. The electrostatic chuck 21 has a base material 23 made of an insulating material such as quartz or the like, and a chuck part 22 disposed on the base material 23 and having a chuck electrode 21a embedded therein. In other words, the electrostatic chuck 21 has a structure in which the chuck part 22 coated with a thermally sprayed film including upper and lower insulating films and a metal film (chuck electrode 21a) embedded therebetween is disposed on the base material 23 made of an insulating material such as quartz. The placing table 20 is configured to be rotatable by a rotation device to be described later.

The substrate processing apparatus 1 has a slip ring 60 made of a metal to supply a chucking voltage (direct current voltage, DC voltage) to the chuck electrode 21a. Therefore, the power supply controller 39 applies the chucking voltage supplied from the DC power supply 37 (direct current power supply) to the chuck electrode 21a via the slip ring 60 and the power supply line 63. Accordingly, a predetermined potential is applied to the chuck electrode 21a. With this configuration, the substrate W can be electrostatically attracted and held on the placing surface 20a.

The power supply controller 39 applies the chucking voltage supplied from the DC power supply 37 to the chuck electrode 21a. The power supply controller 39 applies an RF bias voltage of a predetermined frequency (e.g., 400 kHz) supplied from an RF power supply 36 (high-frequency power supply) to the electrostatic chuck 21 in a state where the substrate W is attracted and held on the placing surface 20a. The RF power supply 36 is connected to a matching box 35. The matching box 35 functions to efficiently apply the RF bias voltage to the electrostatic chuck 21.

The freezing device 30 is disposed below the electrostatic chuck 21. The freezing device 30 is formed by stacking a refrigerator 31 and a refrigeration medium 32. The refrigeration medium 32 is also referred to as “cold link.” The refrigerator 31 holds the refrigeration medium 32, and cools the upper surface of the refrigeration medium 32 to an extremely low temperature. In view of cooling performance, the refrigerator 31 preferably uses a Gifford-McMahon (GM) cycle. The refrigeration medium 32 is fixed on the refrigerator 31, and the upper part thereof is accommodated in the processing chamber 10. The refrigeration medium 32 is made of a material having high thermal conductivity (e.g., Cu), and has a substantially cylindrical outer shape. The center of the freezing device 30 coincides with the central axis Ax of the placing table 20.

The freezing device 30 has a contact surface 30a that is brought into contact with or is separated from a surface to be contacted 20b of the electrostatic chuck 21, and is configured to cool the electrostatic chuck 21. During cooling, the surface to be contacted 20b and the contact surface 30a are brought into contact with each other, thereby cooling the electrostatic chuck 21 to an extremely low temperature. Thereafter, during processing of the substrate W, the surface to be contacted 20b and the contact surface 30a are separated, and the electrostatic chuck 21 is rotated.

For example, the freezing device 30 may be in contact with the surface to be contacted 20b and cool the electrostatic chuck 21 so that the temperature of the substrate W attracted and held on the placing surface 20a becomes 150 K (Kelvin) or lower. Further, the freezing device 30 may be in contact with the surface to be contacted 20b and cool the electrostatic chuck 21 so that the temperature of the substrate W attracted and held on the placing surface 20a becomes 210 K (Kelvin) or lower. At least a part of the freezing device 30 is made of a metal such as copper or the like, and is connected to the ground potential. For example, portions of the freezing device 30 other than the refrigerator 31 are made of copper.

The electrostatic chuck 21 is rotatably supported by the rotation device 40. The rotation device 40 includes a rotation driving device 41, a fixed shaft 45, a rotation shaft 44, a housing 46, magnetic fluid seals 47 and 48, and a stand 49.

The rotation driving device 41 is a direct drive motor having a rotor 42 and a stator 43. The rotor 42 has a substantially cylindrical shape extending coaxially with the rotation shaft 44, and is fixed to the rotation shaft 44. The stator 43 has a substantially cylindrical shape with an inner diameter larger than the outer diameter of the rotor 42. The rotation driving device 41 may be in a form other than a direct drive motor, and may be in a form including a servo motor and a transmission belt.

The rotation shaft 44 has a substantially cylindrical shape that extends coaxially with the central axis Ax of the placing table 20. The fixed shaft 45 is provided inside the rotation shaft 44 in a radial direction. The fixed shaft 45 has a substantially cylindrical shape extending coaxially with the central axis Ax of the placing table 20. A housing 46 is provided outside the rotation shaft 44 in the radial direction. The housing 46 has a substantially cylindrical shape extending coaxially with the central axis Ax of the placing table 20, and is fixed to the processing chamber 10.

The magnetic fluid seal 47 is provided between the outer peripheral surface of the fixed shaft 45 and the inner circumference of the rotation shaft 44. The magnetic fluid seal 47 rotatably supports the rotation shaft 44 with respect to the fixed shaft 45, and seals the gap between the outer peripheral surface of the fixed shaft 45 and the inner circumference of the rotation shaft 44 to separate the processing space 10s of the depressurizable processing chamber 10 from the outer space of the processing chamber 10. Further, the magnetic fluid seal 48 is provided between the inner peripheral surface of the housing 46 and the outer circumference of the rotation shaft 44. The magnetic fluid seal 48 rotatably supports the rotation shaft 44 with respect to the housing 46, and seals the gap between the inner peripheral surface of the housing 46 and the outer circumference of the rotation shaft 44 to separate the inner space 10s of the depressurizable processing chamber 10 from the outer space of the processing chamber 10. Accordingly, the rotation shaft 44 is rotatably supported by the fixed shaft 45 and the housing 46.

The refrigeration medium 32 is inserted into the radially inner side of the fixed shaft 45. The stand 49 is provided between the rotation shaft 44 and the placing table 20, and is configured to transmit the rotation of the rotation shaft 44 to the placing table 20. With the above configuration, when the rotor 42 of the rotation driving device 41 rotates, the rotation shaft 44, the stand 49, and the electrostatic chuck 21 rotate in a X1 direction (see FIG. 1) relative to the refrigeration medium 32.

Further, the freezing device 30 is supported by a lifting device 50 to be vertically movable. The lifting device 50 has an air cylinder 51, a link mechanism 52, a freezing device support 53, a linear guide 54, a fixed portion 55, and a bellows 56.

The air cylinder 51 is a mechanical device whose rod moves linearly by air pressure. The link mechanism 52 converts the linear motion of the rod of the air cylinder 51 into vertical motion of the freezing device support 53. The link mechanism 52 has a lever structure, one end of which is connected to the air cylinder 51 and the other end of which is connected to the freezing device support 53. Accordingly, a large pressing force can be generated with a small thrust of the air cylinder 51. The freezing device support 53 supports the freezing device 30. Further, the moving direction of the freezing device support 53 is guided in the vertical direction by the linear guide 54.

The fixed part 55 is fixed to the bottom surface of the fixed shaft 45. The substantially cylindrical bellows 56 surrounding the refrigerator 31 is provided between the bottom surface of the fixed portion 55 and the upper surface of the freezing device support 53. The bellows 56 is a metal bellows structure that is vertically extensible/contractible. Accordingly, the fixed portion 55, the bellows 56, and the freezing device support 53 seal the gap between the inner peripheral surface of the fixed shaft 45 and the outer circumference of the refrigeration medium 32 to separate the inner space 10s of the depressurizable processing chamber 10 from the outer space of the processing chamber 10. Further, the bottom surface side of the freezing device support 53 is adjacent to the outer space of the processing chamber 10, and the region surrounded by the bellows 56 on the upper surface side of the freezing device support 53 is adjacent to the inner space 10s of the processing chamber 10.

The slip ring 60 is disposed below the rotation shaft 44 and the housing 46. The slip ring 60 has a rotating body 61 including a metal ring and a fixed body 62 including a brush. The rotating body 61 has a substantially cylindrical shape extending coaxially with the rotation shaft 44, and is fixed to the bottom surface of the rotation shaft 44. The fixed body 62 has a substantially cylindrical shape with an inner diameter slightly larger than the outer diameter of the rotating body 61, and is fixed to the bottom surface of the housing 46. The slip ring 60 is electrically connected to the DC power supply 37 and the RF power supply 36. The slip ring 60 supplies the chuck voltage and the RF bias voltage supplied from the DC power supply 37 and the RF power supply 36 to the power supply 63 via the brush of the fixed body 62 and the metal ring of the rotating body 61. With this configuration, the chuck voltage can be applied from the DC power supply 37 to the chuck electrode 21a, and the RF bias voltage can be applied from the RF power supply 36 to the electrostatic chuck 21 without causing torsion or the like in the power supply 63. The slip ring 60 may have a structure other than a brush structure, e.g., a non-contact power supply structure, a structure having a mercury-free liquid or a conductive liquid, or the like.

The cathode part 2 configured to sputter multiple targets T is disposed at an upper portion of the processing chamber 10 to face the placing table 20. The cathode part 2 includes target holders 130, a target cover 140, a gas supply part 150, and a magnet mechanism 170. The target holder 130 holds the multiple targets T that are cathode targets at positions separated upward from the placing table 20. The substrate processing apparatus 1 shown in FIG. 1 has two target holders 130. However, the number of targets T may be two or more, and may be, e.g., four.

The target holders 130 have metal holders 131 for holding the multiple targets T, and insulating members 132 for fixing the outer peripheries of the multiple holders 131 to support the holders 131.

The targets T held by the holders 131 are made of a material having a film forming substance. Each of the targets T is a rectangular flat plate. Further, the substrate processing apparatus 1 may include targets T made of different types of materials. For example, a multilayer film can be formed in the processing chamber 10 by performing sputtering while switching the targets T made of multiple different materials. In other words, the substrate processing apparatus 1 may perform simultaneous sputtering (co-sputtering) in which film formation is performed on multiple targets simultaneously. The substrate processing apparatus 1 according to one embodiment forms a silicon (Si) film or the like on a substrate W, as an example of film formation.

Each of the holders 131 is formed in a rectangular shape that is considerably larger than the target T in plan view. Each of the holders 131 is fixed to the inclined surface of the ceiling 10a via an insulating member 132. Since each of the holders 131 is fixed to the inclined surface of the ceiling 10a, each of the holders 131 holds the surfaces (sputtering surfaces exposed to the processing space 10s) of the multiple targets T while being inclined with respect to the central axis Ax.

The power supply connected to the cathode part 2 may include one or both of a direct current (DC) power supply or a radio frequency (RF) power supply, but is not limited thereto. When the power supply connected to the cathode part 2 includes only a DC power supply, the magnet 171 uses a DC magnet to perform sputtering. When the power supply connected to the cathode 2 includes both a DC power supply and an RF power supply, the magnet 171 uses a point-cusp-magnetic field (PCM) magnet to activate ionized particles and perform sputtering. Hereinafter, a case where the power supply connected to the cathode part 2 includes both a direct current power supply 191 (DC power supply) and a radio frequency power supply 137 (RF power supply) will be described as an example.

The target holder 130 electrically connects the DC power supplies 191 to the targets T held by the holders 131. Each of the multiple DC power supplies 191 has one end connected to a ground potential and the other end connected to a low pass filter (LPF) 193, and applies a pulse wave of a negative DC voltage to the target T. Further, the DC power supply 191 may be a single power supply that selectively applies a negative DC voltage to each of the multiple targets T.

The RF power supply 137 has one end connected to a ground potential and the other end connected to a power supply line that connects the DC power supply 191 and the holder 131 via a matching device 136. Therefore, the holders 131 are connected to the RF power supplies 137 via the matching devices 136. The RF power supplies 137 apply an RF voltage superimposed on a DC voltage from the holders 131 to the targets T. The matching devices 136 function to efficiently apply the RF voltage to the targets T.

Accordingly, sputtering can be performed by superimposing a negative DC voltage pulse wave and an RF voltage, and the sputtered particles can be ionized with high efficiency. Further, by using the magnet 171 that generates PCM that is a local magnetic field, for plasma discharge, the ionization efficiency can be further increased. As a result, the generated ionized sputtered particles can be attracted to the electrostatic chuck 21 by the RF bias voltage, and the embedding accuracy of a Cu film formed and attached to the substrate W can be improved.

The RF power applied by the RF power supply 137 has a frequency in a VHF band (e.g., 60 MHZ) and is preferably 30 KW or less. The RF power supply 137 may be a single power supply that selectively applies an RF voltage to each of the multiple targets T. The low pass filter (LPF) 193 is disposed in the power supply line between the DC power supply 191 and the holder 131, and functions as an RF filter to prevent the RF voltage supplied from the RF power supply 137 from flowing into the DC power supply 191.

The cathode part 2 has first shield members (adhesion preventive shields) 135 made of a metal that surrounds the outer peripheries of the targets T held by the holders 131. The first shield member 135 has an opening through which the target T is exposed, and is attached to the inclined surface of the ceiling 10a via an insulating member 132. In other words, the insulating member 132 is disposed between the processing chamber 10 connected to the ground potential and the first shield member 135. Therefore, the first shield member 135 and the holder 131 are not electrically connected.

A pulse oscillator 192 is disposed between the DC power supply 191 and the RF power supply 137 and connected to both power supplies. The pulse oscillator 192 synchronizes the pulse frequency of the DC voltage pulse wave from the DC power supply 191 with the frequency of the RF power (RF voltage) from the RF power supply 137. Accordingly, it is possible to superimpose the negative DC voltage and the RF voltage to sputter the targets T while reducing the power loss of both the negative DC voltage pulse wave and the RF voltage.

The magnet mechanism 170 applies magnetic field to each of the targets T. By applying the magnetic field to each of the targets T, the magnet mechanism 170 induces plasma to the targets T. For each of the multiple holders 131, the magnet mechanism 170 has a magnet 171 (cathode magnet) and an operating part 172 that operably holds the magnet 171. In other words, the magnet 171 can be driven by the operating part 172. In the example of FIG. 1, two magnets 171 and two operating parts 172 for holding the two magnets 171 are provided to correspond to the two holders 131.

The magnets 171 are formed in the same shape. Further, the magnets 171 generate the magnetic force of substantially the same magnitude. Specifically, each of the magnets 171 has a substantially rectangular shape in plan view. In a state where the operating part 172 is held, the long side of the magnet 171 extends parallel to the lateral direction of the rectangular target T, and the short side of the magnet 171 extends parallel to the longitudinal direction of the rectangular target T.

A permanent magnet can be used for each of the magnets 171. The material forming each of the magnets 171 is not particularly limited as long as it has an appropriate magnetic force, and may be iron, cobalt, nickel, samarium, and neodymium.

The operating parts 172 for holding the magnets 171 reciprocate the magnets 171 along the longitudinal direction of the targets T. In other words, the magnets 171 are movably provided. Further, the operating parts 172 for holding the magnets 171 move the magnets 171 to be close to and distant from the targets T. Specifically, each operating part 172 includes a reciprocating mechanism 174 for holding and reciprocating the magnets 171, and an approaching/separating mechanism 175 for holding and moving the reciprocating mechanism 174 to be close to or distant from the target T.

The target cover 140 has a second shield member 141 disposed in the processing chamber 10, and a support part 142 for operably supports the second shield member 141.

The second shield member 141 is disposed between the targets T and the placing table 20. The second shield member 141 is formed in a pyramid shape that is approximately parallel to the inclined surface of the ceiling 10a of the processing chamber 10. The second shield member 141 can face the sputtering surfaces of the multiple targets T. The second shield member 141 has an opening 141a corresponding to the target T. The opening 141a is slightly greater than the target T, and moves by the rotation of the second shield member 141.

The opening 141a is disposed to face one target T (selected target Ts) of the multiple targets T by the rotation of the support part 142. Since the opening 141a is disposed to face the selected target Ts, the second shield member 141 exposes only the selected target Ts to the substrate W on the placing table 20. The second shield member 141 prevents the other targets T (non-selected targets) from being exposed.

The support part 142 has a columnar rotation shaft 143 and a rotation part 144 for rotating the rotation shaft 143. The axis of the rotation shaft 143 overlaps the central axis Ax of the processing chamber 10. The rotation shaft 143 extends along the vertical direction, and fixes the center (vertex) of the second shield member 141 at the lower end thereof. The rotation shaft 143 penetrates through the center of the ceiling 10a and protrudes to the outside of the processing chamber 10.

The rotation part 144 is disposed outside the processing chamber 10, and rotates the rotation shaft 143 relative to an upper end connector 145 holding the rotation shaft 143 via a rotation transmission part (not shown). Accordingly, the rotation shaft 143 and the second shield member 141 rotate around the central axis Ax. Hence, the target cover 140 can adjust the circumferential position of the opening 141a, and the opening 141a can face the selected target Ts to be sputtered.

The substrate processing apparatus 1 uses the target cover 140 to perform sputtering while switching the targets. However, the substrate processing apparatus 1 may not include the target cover 140, and perform simultaneous sputtering.

The gas supply part 150 is disposed at the ceiling 10a and supplies an excitation gas. The gas supply part 150 has a line 152 for circulating a gas outside the processing chamber 10. The gas supply part 150 has a gas source 153, a flow rate controller 154, and a gas inlet 155 in that order from the upstream side toward the downstream side of the line 152.

The gas source 153 stores an excitation gas (e.g., argon gas). The gas source 153 supplies a gas to the line 152. The flow rate controller 154 is, e.g., a mass flow controller, and adjusts the flow rate of the gas supplied into the processing chamber 10. The gas inlet 155 introduces a gas from the outside to the inside of the processing chamber 10. The gas inlet 155 is a gas channel penetrating through the ceiling 10a.

The gas outlet (not shown) of the substrate processing apparatus 1 has a vacuum pump and an adapter for fixing the vacuum pump to the bottom portion of the processing chamber 10. The gas outlet decreases a pressure in the processing space 10s of the processing chamber 10.

The controller (not shown) is a computer, and has a central processing unit (CPU), an input device, an output device, a display device, a memory, or the like. The CPU calls a specific processing recipe stored in the memory or another storage medium, and causes the substrate processing apparatus 1 to perform sputtering based on the processing recipe.

### Shield Member

The substrate processing apparatus 1 is provided with adhesion prevention devices referred to as shields (the first shield members 135 and the second shield member 141) in the processing chamber 10 in order to prevent contamination of the substrate W and the cathode part 2 of the sputtering source and suppress generation of particles.

However, in the ionized sputtering film formation performed in the substrate processing apparatus 1, the film formation time in a single process becomes long, and the film attached to the shield becomes thick in a short period of time. The thermal effect of the shield increases due to the exposure to plasma for a long period of time, and repeated thermal expansion and contraction of the shield causes cracks in the film attached to the shield, which results in peeling off of the film. As a result, particle generation and contamination occur in the processing chamber 10.

The film attached to the shields is concentrated near the targets T and substrate W, so that cracks or the like occur in the film. Accordingly, a thick film-shaped material grows into a sharp metal object, which results in a structure that is likely to concentrate charges. Hence, in the cathode part 2, the surface of the metal object is charged (charged up) by the charges concentrated at the metal object, thereby causing abnormal discharge (micro-arc discharge).

Therefore, in ionized sputtering film formation, it is important to suppress peeling off of the film during sputtering. Further, in the cathode part 2, it is important to prevent the surface of the metal object grown from the film attached to the shield from being charged and causing abnormal discharge. Further, in the case of fixing the second shield member 141, it is important to prevent a screw head from being exposed to the processing space 10s (discharge space) and causing abnormal discharge.

Thus, in the substrate processing apparatus 1 according to the present embodiment, the cathode part 2 is not negatively charged, and is unlikely to be reversely sputtered. Further, negative charges are released from the cathode part 2, and a degree of adhesion to the first shield member 135 is lowered. Further, a shield cap 160 for shielding the screw head is installed without exposing the screw head for fixing the second shield member 141 to the processing space 10s. Further, the peeling off of the film does not occur even when a film is formed on the shield cap 160, and the shield cap 160 is not loosened even by the movement caused by the rotational movement of the second shield member 141.

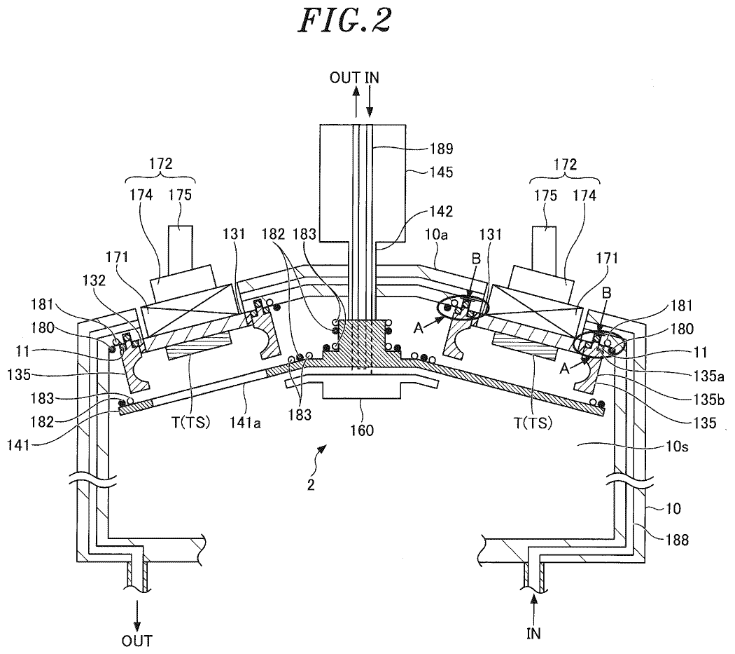

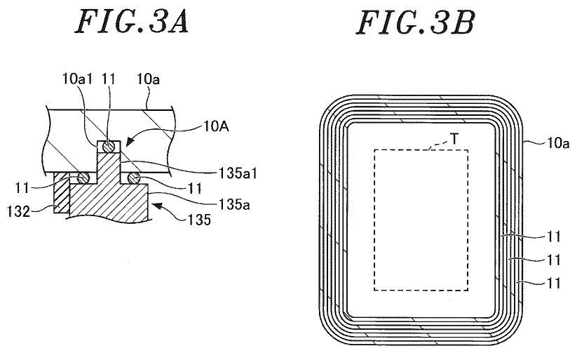

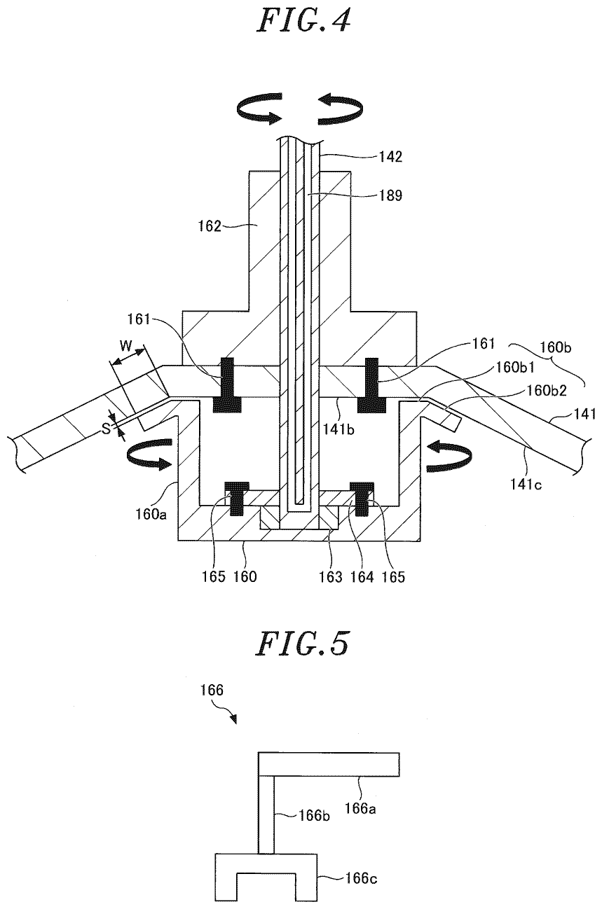

The configurations of the first shield member 135, the second shield member 141, and the shield cap 160 of the cathode part 2 will be described with reference to FIGS. 2 to 5. FIG. 2 is an enlarged view of the cathode part 2. FIGS. 3A and 3B show an example of the configuration of the first shield member 135. FIG. 4 shows an example of the configuration of the second shield member 141 and the shield cap 160. FIG. 5 shows an example of a tool for attaching the shield cap 160. In FIG. 2, the DC power supply 191 and the RF power supply 137 that apply a DC voltage and an RF voltage to the target T, the gas supply part 150, and the neighboring parts of the placing table 20 are omitted.

### First Shield Member

The first shield member 135 is attached to the outer periphery of the target T on the ceiling 10a as shown in A area of FIG. 2. FIG. 3A is an example of A area of FIG. 2. A recess 10a1 is formed at the outer periphery of the target T on the ceiling 10a. The recess 10a1 is formed to surround the outer periphery of the target T.

As shown in FIGS. 2 and 3A, the first shield member 135 has an attachment portion 135a and a shield body 135b. The attachment portion 135a has a protrusion 135a1 that can be inserted into the recess 10a1 of the ceiling 10a. The shield body 135b is an adhesion prevention shield surrounding the target T, and is attached to the ceiling 10a by the attachment portion 135a. The protrusion 135a1 has a width slightly smaller than that of the recess 10a1, and the depth from the top surface to the bottom surface of the recess 10a1 and the height of the protrusion 135a1 may be approximately the same. The first shield member 135 is attached to the ceiling 10a and suspended from the ceiling 10a by fitting the protrusion 135a1 of the attachment portion 135a into the recess 10a1. In this case, shield spirals 11 are installed between the bottom surface of the recess 10a1 and the upper surface of the protrusion 135a1. The shield spiral 11 is a spiral-shaped elastic body made of a metal or the like, and electrically connects the ceiling 10a and the first shield member 135. Further, two shield spirals 11 are installed between the facing surfaces of the attachment portion 135a and the ceiling 10a on the inner peripheral side and the outer peripheral side of the recess 10a1 and the protrusion 135a1.

FIG. 3B shows an example of a B-B cross section of FIG. 2, and is a plan view of three shield spirals 11. The three shield spirals 11 are provided in three rows to surround the target T between the recess 10a1 of the ceiling 10a and both sides of the recess 10a1 and the protrusion 135a1 of the attachment portion 135a and both sides of the protrusion 135a1.

The ceiling 10a is grounded. Therefore, by bringing the recess 10a1 and the protrusion 135a1 into contact with each other and installing the three shield spirals 11, the first shield member 135 can be reliably at ground potential. Accordingly, it is possible to provide a hardware configuration in which the first shield member 135 is not negatively charged and the first shield member 135 is unlikely to be reversely sputtered. Further, by forming the recess 10a1 at the ceiling 10a and forming the protrusion 135a1 at the attachment portion 135a, the ground contact area can be increased. In addition, by arranging the three shield spirals 11 at irregular portions between the ceiling 10a and the attachment portion 135a, the ground contact area can become wider. By increasing the ground contact area, negative charges can be released more easily. Hence, the occurrence of abnormal discharge can be avoided.

The configuration of the first shield member 135 at the outer periphery of the target T on the left side of FIG. 2 is the same as the configuration of the first shield member 135 on the target T side on the right side, so that the description thereof will be omitted.

The recess 10a1 formed in the ceiling 10a is an example of an engagement portion 10A formed at the outer periphery of the target T on the ceiling 10a. The engagement portion 10A and the attachment portion 135a have recesses and/or protrusions that fit together. For example, the recess of the engagement portion 10A may fit into the protrusion of the attachment portion 135a, or the protrusion of the engagement portion 10A may fit into the recess of the attachment portion 135a, or both cases may be applied. The shield spirals 11 are provided between the horizontal surface of the recess formed in the ceiling 10a and the horizontal surface of the protrusion of the attachment portion 135a, and/or between the horizontal surface of the protrusion formed in the ceiling 10a and the horizontal surface of the recess of the attachment portion 135a. The shield spiral 11 is an example of a conductive sealing member that electrically connects the ceiling 10a and the first shield member 135. Accordingly, a larger ground surface area is ensured between the engagement portion 10A and the attachment portion 135a, and negative charges are easily released from the first shield member 135 through the shield spirals 11, which makes it possible to avoid occurrence of abnormal discharge.

As shown in FIG. 2, a lamp heater 180 is disposed at the contact portion between the first shield member 135 and the ceiling 10a. A first flow path 181 is formed at the ceiling 10a near the lamp heater 180.

The first shield member 135 is thermally affected by the plasma generated from the excitation gas. Therefore, in the first shield member 135, the lamp heater 180 and the first flow path 181 are arranged adjacent to each other. Accordingly, the first shield member 135 is heated by the lamp heater 180, and the first shield member 135 is cooled (temperature controlled) by circulating a temperature control medium through the first flow path 181. Hence, the thermal effect of the plasma can be reduced, and the peeling off of the film attached to the first shield member 135 can be suppressed. Further, the process temperature in the processing chamber 10 can be controlled to be within a range of room temperature to 200° C.

The lamp heater 180 and the first flow path 181 are an example of a first temperature control mechanism disposed at the outer periphery of the first shield member 135 on the ceiling 10a. The lamp heater 180 is an example of a first heat source that performs heating. The first flow path 181 is an example of a flow path through which a temperature control medium such as water or Galden flows.

### Second Shield Member

Similarly, the second shield member 141 is thermally affected by the plasma. Therefore, the pipes forming a sheath heater 182 and a second flow path 183 are arranged adjacent to the second shield member 141. Accordingly, the second shield member 141 is heated by the sheath heater 182, and the second shield member 141 is cooled (temperature controlled) by circulating a temperature control medium through the second flow path 183. Hence, the thermal effect of the plasma can be reduced, and the peeling off of the film attached to the second shield member 141 can be suppressed. Further, the process temperature in the processing chamber 10 can be controlled to be within a range of room temperature to 200° C.

The sheath heater 182 and the second flow path 183 are an example of a second temperature control mechanism disposed at the second shield member 141. The sheath heater 182 is an example of a second heat source that performs heating, and the second flow path 183 is an example of a flow path through which a temperature control medium such as water or Galden flows. The first heat source and the second heat source are different heat sources, and the first flow path 181 and the second flow path 183 are different flow paths.

The lamp heater 180 can be fixed to the first shield member 135. On the other hand, the sheath heater 182 needs to be completely in contact with the second shield member 141 in order to obtain thermal conduction, and thus is attached to the second shield member 141 by brazing, welding, or the like. The pipe forming the second flow path 183 is adjacent to the lamp heater 180 and attached to the second shield member 141 by brazing or the like.

The pair of sheath heaters 182 and the pair of second flow path 183 are disposed on the outer peripheral side and the central side of the second shield member 141, respectively. Accordingly, the temperature non-uniformity between the outer periphery and the center of the second shield member 141 can be eliminated.

In other words, the second temperature adjustment mechanism has the pipes forming the multiple second flow paths 183 and the multiple sheath heaters 182. At least one of the pipes forming the second flow paths 183 and at least one of the sheath heaters 182 may be disposed adjacent to the outer periphery of the second shield member 141. Further, the pipes forming the other second flow paths 183 and the other sheath heaters 182 may be provided adjacent to the center of the second shield member 141.

### Shield Cap

The shield cap 160 is configured such that the screw head for fixing the second shield member 141 is not exposed to the processing space 10s to prevent abnormal discharge. The configuration of the shield cap 160 will be described with reference to FIG. 4. FIG. 4 shows an enlarged cross section of the shield cap 160 and the peripheral part thereof.

The shield cap 160 has a cylindrical cap body 160a with a bottom portion and a flange portion 160b. The shield cap 60 is hollow. The flange 160b has a horizontal portion 160b1 attached from the opening of the cap body 160a toward the outside, and an inclined portion 160b2 extending from the horizontal portion 160b1. The support part 142 penetrates through a shaft portion 162, and screw-fixes the shaft portion 162 that supports the support part 142 to the second shield member 141. The shield cap 160 covers screws 161 so that the screws 161 are not exposed to the processing space 10s.

The shield cap 160 fixes the support part 142 by attaching the tip end of the support part 142 to a rotation shaft connecting nut 163. The shield cap 160 presses the rotation shaft connecting nut 163 from the inside of the shield cap 160 toward a pressing plate 164 to be screw-fixed to the pressing plate 164 by the screws 165.

The surfaces of the second shield member 141 and the shield cap 160 except the screw bearing surface are blasted. A gap S between the surface of the second shield member 141 and the surface of the inclined portion 160b2 of the flange portion 160b that face each other is controlled such that the friction between the second shield member 141 and the shield cap 160 do not occur. The shield cap 160 is fastened to the support part 142 by rotating the shield cap 160 using a dedicated tool. For example, as shown in FIG. 5, a dedicated tool 166 is combination of a torque wrench 166a and a tightening clamp 166c. The dedicated tool 166 includes the torque wrench 166a, an extension bar 166b, and the clamp 166c, and the shield cap 160 is tightened by rotating the shield cap 160 with the torque wrench 166a while holding the shield cap 160 with the clamp 166c. The tightening torque of the shield cap 160 is 5 Nm or less.

The gap S between the second shield member 141 and the shield cap 160 shown in FIG. 4 is preferably small as long as the friction between the second shield member 141 and the shield cap 160 can be avoided, and is 2 mm or less.

Further, the flange 160b has a horizontal portion 160b1 corresponding to a horizontal back surface 141b of the second shield member 141, and an inclined portion 160b2 corresponding to the inclined surface 141c continuing from the horizontal back surface 141b of the second shield member 141 to correspond to the pyramid shape of the second shield member 141. The gap S is the gap between the inclined surface 141c and the inclined portion 160b2.

The length of the inclined portion 160b2 of the flange 160b is preferably 9.5 mm to prevent the film from reaching the shield cap 160.

The second shield member 141 is exposed to plasma and is grounded. Therefore, the second shield member 141 is made of aluminum that is a material having high thermal conductivity. The shield cap 160 is made of stainless steel in consideration of thermal conductivity and strength. The shield cap 160 may be made of stainless steel coated with a thermal conductive material. The support part 142 and the holding plate 164 are made of stainless steel.

With this configuration, the screws 161 and 165 for fixing the second shield member 141 and the support part 142 are not exposed to the processing space 10s that is a discharge space. As a result, it is possible to avoid abnormal discharge caused by exposure of the metal screws 161 and 165 to plasma.

### Other Water Passages

Other water passages will be described with reference to FIGS. 2 and 4. The substrate processing apparatus 1 has two water passage systems in the processing chamber 10 and the support part 142. A first system is a water passage in which an opening for inputting (IN) and outputting (OUT) a temperature control medium such as water is formed at the bottom portion of the processing chamber 10 and the temperature control medium circulates through a flow path (third flow path 188) formed in the bottom portion, the side portion, and the wall of the ceiling 10a of the processing chamber 10. The temperature control medium (cooling water or hot water) that flows through the third flow path 188 returns to a chiller unit (not shown), is subjected to temperature control, and circulates through the third flow path 188.

The second system is a water passage in which the temperature control medium circulates through a flow path (fourth flow path 189) having a forward path and a return path formed in the support part 142. The outward path and the return path are connected at the tip end of the support part 142. The temperature control medium (cooling water or hot water) that flows through the fourth flow path 189 returns to the chiller unit, is subjected to temperature control, and circulates through the fourth flow path 189. With this configuration, the temperatures of the temperature control media flowing through the third flow path 188 and the fourth flow path 189 can be separately controlled, thereby separately controlling the temperatures of the support part 142 and the inside of the processing chamber 10.

As described above, in the substrate processing apparatus 1 according to the present embodiment, the cathode part 2 is not negatively charged, and the cathode part 2 is less likely to be reversely sputtered. Further, the negative charge can be easily released from the cathode part 2, and a degree of adhesion to the first shield member 135 can be lowered. Moreover, the screws for fixing the second shield member 141 are covered with the shield cap 160 so that they are not exposed to the processing space 10s. Accordingly, abnormal discharge can be prevented. In addition, by controlling the tightening of the shield cap 160 with the dedicated tool 166, the shield cap 160 is not loosened even by the movement caused by the rotational movement of the second shield member 141, and the peeling off of the film does not occur even if a film is formed on the shield cap 160.

It should be noted that the substrate processing apparatus according to the embodiments of the present disclosure are illustrative in all respects and are not restrictive. The above-described embodiments may be modified and improved in various forms without departing from the scope of the appended claims and the gist thereof. The above-described embodiment may include other configurations without contradicting each other and may be combined without contradicting each other.

1. A substrate processing apparatus comprising:
a processing chamber having a ceiling; and
a cathode part installed at the ceiling and configured to sputter a target,
wherein the ceiling has an engagement portion around the target, and
the cathode part includes:
a first shield member having an attachment portion to be attached to the engagement portion; and
a conductive seal member configured to electrically connect the ceiling and the first shield member.

2. The substrate processing apparatus of claim 1, wherein the engagement portion and the attachment portion have a recess and/or a protrusion that fit together, and
the conductive seal member is disposed between the recess of the engagement portion and the protrusion of the attachment portion that fit together and/or between the protrusion of the engagement portion and the recess of the attachment portion that fit together.

3. The substrate processing apparatus of claim 1, further comprising:
a support part which is rotatable and penetrates through the center of the ceiling;
a second shield member supported by the support part and having an opening corresponding to the target by rotation of the support part; and
a shield cap configured to prevent a screw for fixing the support part and the second shield member from being exposed to a processing space.

4. The substrate processing apparatus of claim 1, further comprising:
a first temperature adjustment mechanism disposed at the ceiling around the first shield member.

5. The substrate processing apparatus of claim 4, wherein the first temperature adjustment mechanism includes a first heat source configured to perform heating, and a first flow path through which a temperature adjustment medium flows.

6. The substrate processing apparatus of claim 5, wherein the first flow path and the first heat source are adjacent to each other.

7. The substrate processing apparatus of claim 3, further comprising:
a second temperature adjustment mechanism disposed at the second shield member.

8. The substrate processing apparatus of claim 7, wherein the second temperature control mechanism has a second heat source configured to perform heating and a second flow path through which a temperature control medium flows.

9. The substrate processing apparatus of claim 8, wherein the second flow path and the second heat source are disposed adjacent to each other.

10. The substrate processing apparatus of claim 8, wherein the second flow path and the second heat source are bonded to the second shield member.

11. The substrate processing apparatus of claim 3, further comprising:
a third flow path formed in a wall of the processing chamber and a fourth flow path formed in the support part,
wherein the third flow path and the fourth flow path are different from each other.

12. The substrate processing apparatus of claim 8, wherein the second temperature adjustment mechanism has a plurality of the second flow paths and a plurality of the second heat sources,
wherein at least one of the plurality of the second flow paths and at least one of the plurality of the second heat sources are adjacently disposed at the outer periphery of the second shield member, and the other plurality of the second flow paths and the other plurality of the second heat sources are adjacently disposed at the center of the second shield member.

13. The substrate processing apparatus of claim 3, wherein the shield cap has a flange, and
a gap between the second shield member and the flange is 2 mm or less.

14. The substrate processing apparatus of claim 13, wherein the shield cap is made of stainless steel.

15. The substrate processing apparatus of claim 13, wherein the shield cap and the second shield member are blasted.
